(19) United States
(12) Patent Application Publication
(10) Pub. No.: US 2026/0291439 A1
(43) Pub. Date: Sep. 24, 2026

(54) POWER MANAGEMENT CIRCUIT

(71) Applicant: Qorvo US, Inc., Greensboro, NC (US)

(72) Inventor: Nadim Khlat, Cugnaux (FR)

(21) Appl. No.: 18/996,147

(22) PCT Filed: Jul. 5, 2023
(86) PCT No.: PCT/US2023/026885

§ 371 Date: Jan. 17, 2025

Related U.S. Application Data
(60) Provisional application No. 63/397,025, filed on Aug. 11, 2022.

(51) Int. Cl. H03F 1/02; H03F 3/195; H03F 3/24

(52) U.S. Cl. CPC H03F 1/0222; H03F 3/195; H03F 3/245; H03F 2200/102; H03F 2200/165; H03F 2200/324

(57) ABSTRACT

A power management circuit is provided. Herein, a transceiver circuit is configured to generate a modulated differential signal that includes information related to a time-variant amplitude of a radio frequency (RF) signal. Accordingly, a power management integrated circuit (PMIC) can generate a modulated voltage, a modulated phase correction voltage, and a modulated amplitude correction voltage based on the modulated differential signal. The modulated voltage is provided to a power amplifier circuit for amplifying the RF signal, and the modulated phase correction voltage and the modulated amplitude correction voltage are provided to a power amplifier circuit to cause phase and amplitude adjustment in the RF signal. By performing phase and amplitude adjustment in the RF signal, it is possible to ensure proper aliment between the modulated voltage and the time-variant amplitude of the RF signal to thereby avoid potential distortion in the RF signal.

### RELATED APPLICATIONS

This application claims the benefit of U.S. provisional patent application Ser. No. 63/397,025, filed on Aug. 11, 2022, the disclosure of which is hereby incorporated herein by reference in its entirety.

### FIELD OF THE DISCLOSURE

The technology of the disclosure relates generally to a power management circuit capable of supporting both envelope tracking (ET) and average power tracking (APT) operations.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

A fifth-generation new radio (5G-NR) wireless communication system is widely regarded as a technological advancement that can achieve significantly higher data throughput, improved coverage range, enhanced signaling efficiency, and reduced latency compared to the existing third-generation (3G) and fourth-generation (4G) communication systems. A 5G-NR mobile communication device usually transmits and receives a radio frequency (RF) signal(s) in a millimeter wave (mmWave) RF spectrum that is typically above 6 GHz. Notably, the RF signal(s) transmitted in the mmWave RF spectrum may be more susceptible to propagation attenuation and interference that can result in substantial reduction in data throughput. To help mitigate propagation attenuation and maintain desirable data throughput, the 5G-NR mobile communication device employs a power amplifier(s) to amplify the RF signal(s) before transmitting in the mmWave RF spectrum.

Envelope tracking (ET) and average power tracking (APT) are power management techniques designed to improve operating efficiency of the power amplifier(s). Specifically, the power amplifier(s) is configured to amplify the RF signal(s) based on a modulated voltage (ET modulated or APT modulated) that closely tracks a time-variant power envelope of the RF signal(s). The modulated voltage is typically generated by a power management integrated circuit (PMIC) that is typically separated from the power amplifier(s). As such, it is possible that the modulated voltage can become misaligned in phase and/or amplitude from the time-variant power envelope of the RF signal(s) to potentially distort the RF signal at the power amplifier(s). As such, it is desirable to align the modulated voltage with the time-variant power envelope of the RF signal(s), both in phase and amplitude, at the power amplifier(s).

### SUMMARY

Embodiments of the disclosure relate to a power management circuit. Herein, a transceiver circuit is configured to generate a modulated differential signal that includes information related to a time-variant amplitude of a radio frequency (RF) signal. Accordingly, a power management integrated circuit (PMIC) can generate a modulated voltage, a modulated phase correction voltage, and a modulated amplitude correction voltage based on the modulated differential signal. The modulated voltage is provided to a power amplifier circuit for amplifying the RF signal, and the modulated phase correction voltage and the modulated amplitude correction voltage are provided to a power amplifier circuit to cause phase and amplitude adjustment in the RF signal. By performing phase and amplitude adjustment in the RF signal, it is possible to ensure proper alignment between the modulated voltage and the time-variant amplitude of the RF signal to thereby avoid potential distortion in the RF signal.

In one aspect, a power management circuit is provided. The power management circuit includes a transceiver circuit. The transceiver circuit is configured to generate a digital signal having a time-variant amplitude. The transceiver circuit is also configured to convert the digital signal into an RF signal associated with the time-variant amplitude. The transceiver circuit is also configured to generate a modulated differential signal based on the time-variant amplitude. The power management circuit also includes a PMIC. The PMIC is configured to generate a modulated voltage, a modulated amplitude correction voltage, and a modulated phase correction voltage based on the modulated differential signal.

In another aspect, a transceiver circuit is provided. The transceiver circuit includes a first signal processing circuit. The first signal processing circuit is configured to generate a digital signal having a time-variant amplitude. The first signal processing circuit is also configured to convert the digital signal into an RF signal associated with the time-variant amplitude. The transceiver circuit also includes a second signal processing circuit. The second signal processing circuit is configured to generate a modulated differential signal based on the time-variant amplitude.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary power management circuit that can be configured according to various embodiments of the present disclosure to align a modulated voltage with a time-variant amplitude of a radio frequency (RF) signal at a power amplifier circuit;

FIG. 2 is a schematic diagram providing an exemplary illustration of the power management circuit of FIG. 1 configured according to one embodiment of the present disclosure;

FIG. 3 is a schematic diagram providing an exemplary illustration of a digital differential signal generated according to the embodiment of FIG. 2;

FIG. 4 is a schematic diagram providing an exemplary illustration of the power management circuit of FIG. 1 configured according to another embodiment of the present disclosure;

FIG. 5 is a schematic diagram providing an exemplary illustration of a digital differential signal generated according to the embodiment of FIG. 4;

FIG. 6 is a schematic diagram providing an exemplary illustration of the power management circuit of FIG. 1 configured according to another embodiment of the present disclosure;

FIG. 7 is a schematic diagram providing an exemplary illustration of a digital differential signal generated according to the embodiment of FIG. 6; and

FIG. 8 is a schematic diagram of an exemplary user element wherein the power management circuits of FIGS. 2, 4, and 6 can be provided.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a power management circuit. Herein, a transceiver circuit is configured to generate a modulated differential signal that includes information related to a time-variant amplitude of a radio frequency (RF) signal. Accordingly, a power management integrated circuit (PMIC) can generate a modulated voltage, a modulated phase correction voltage, and a modulated amplitude correction voltage based on the modulated differential signal. The modulated voltage is provided to a power amplifier circuit for amplifying the RF signal, and the modulated phase correction voltage and the modulated amplitude correction voltage are provided to a power amplifier circuit to cause phase and amplitude adjustment in the RF signal. By performing phase and amplitude adjustment in the RF signal, it is possible to ensure proper alignment between the modulated voltage and the time-variant amplitude of the RF signal to thereby avoid potential distortion in the RF signal.

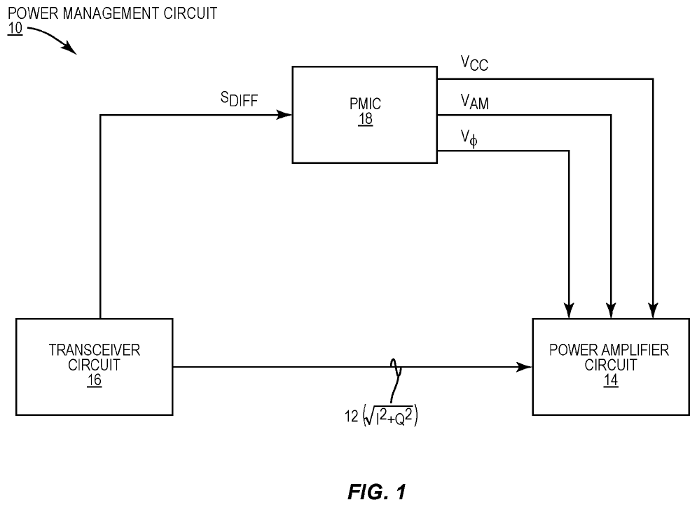

FIG. 1 is a schematic diagram of an exemplary power management circuit 10 that can be configured according to various embodiments of the present disclosure to align a modulated voltage Vcc with a time-variant amplitude \sqrt{I²+Q²} of an RF signal 12 at a power amplifier circuit 14. The power management circuit 10 further includes a transceiver circuit 16 and a PMIC 18, both are separated from the power amplifier circuit 14 and each other. The transceiver circuit 16 is configured to generate the RF signal 12 associated with the time-variant amplitude \sqrt{I²+Q²} and provide the RF signal 12 to the power amplifier circuit 14.

The transceiver circuit 16 is further configured to generate a modulated differential signal SDIFF based on the time-variant amplitude \sqrt{I²+Q²} of the RF signal 12 and provide the modulated differential signal S_{DIFF} to the PMIC 18. As discussed in detail below, the modulated differential signal S_{DIFF} can be generated based on various embodiments of the present disclosure to include such information that enables the PMIC 18 to generate a modulated phase correction voltage V_{φ} and a modulated amplitude voltage V_{AM}, in addition to the modulated voltage V_{CC}. The modulated phase correction voltage V_{υ} and the modulated amplitude voltage V_{AM} can be provided to the power amplifier circuit 14 to cause phase and amplitude correction in the RF signal 12 such that the time-variant amplitude \sqrt{I²+Q²} of the RF signal 12 can be properly aligned with the modulated voltage V_{CC} at the power amplifier circuit 14. As a result, it is possible to prevent potential distortion (e.g., amplitude clipping) in the RF signal 12 when the RF signal 12 is amplified at the power amplifier circuit 14.

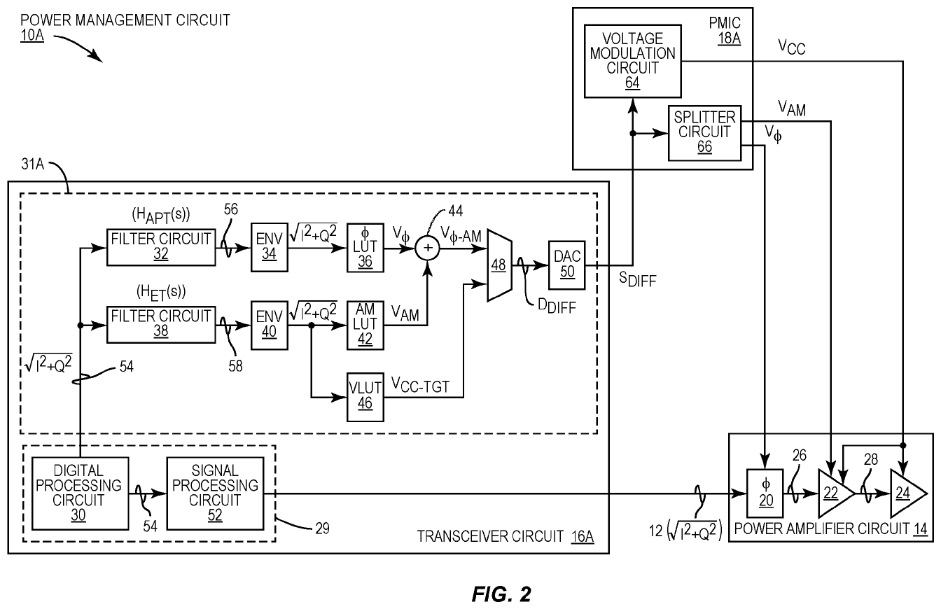

FIG. 2 is a schematic diagram providing an exemplary illustration of a power management circuit 10A configured according to one embodiment of the present disclosure. Common elements between FIGS. 1 and 2 are shown therein with common element numbers and will not be re-described herein.

Herein, the power management circuit 10A includes a transceiver circuit 16A and a PMIC 18A that are functionally equivalent to the transceiver circuit 16 and the PMIC 18 in FIG. 1. The power amplifier circuit 14 includes a phase shifter circuit 20, a driver stage amplifier 22, and an output stage amplifier 24. The phase shifter circuit 20 is configured to perform phase correction on the RF signal 12 based on the modulated phase correction voltage Vo to generate a phase-adjusted RF signal 26. The driver stage amplifier 22 is coupled to the phase shifter circuit 20. The driver stage amplifier 22 first performs an amplitude adjustment on the phase-adjusted RF signal 26 based on the modulated amplitude correction voltage V_{AM} to generate a phase-amplitude-adjusted RF signal 28 and then amplifies the phase-amplitude-adjusted RF signal 28 based on the modulated voltage V_{CC}. The output stage amplifier 24 is coupled to the driver stage amplifier 22 and configured to further amplify the phase-amplitude-adjusted RF signal 28 based on the modulated voltage V_{CC}.

According to an embodiment of the present disclosure, the transceiver circuit 16A includes a first signal processing circuit 29 that includes a digital processing circuit 30. The transceiver circuit 16A also includes a second signal processing circuit 31A, which includes a first filter circuit 32, a first envelope detector 34, a phase correction lookup table (LUT) circuit 36, a second filter circuit 38, a second envelope detector 40, an amplitude correction LUT circuit 42, a combiner 44, a voltage LUT circuit 46, a modulator circuit 48, and a digital to analog converter (DAC) 50. The first signal processing circuit 29 further includes a signal processing circuit 52. The digital processing circuit 30 is configured to generate a digital signal 54 associated with the time-variant amplitude \sqrt{I²+Q²}. The signal processing circuit 52 is configured to convert the digital signal 54 into the RF signal 12, which understandably is also associated with the time variant amplitude \sqrt{I²+Q²}, and provide the RF signal 12 to the phase shifter circuit 20 in the power amplifier circuit 14. In a non-limiting example, the signal processing circuit 52 can include additional active/passive circuits (e.g., DAC, frequency converter, etc.), which are omitted herein for the sake of simplicity.

The first filter circuit 32 is configured to apply a first complex filter HAPT(s) to the digital signal 54 to generate a first equalized digital signal 56. The first envelope detector 34 is configured to detect the time-variant amplitude \sqrt{I²+Q²} of the first equalized digital signal 56. The phase correction LUT circuit 36 may include an isophase LUT (not shown) and is configured to generate the modulated phase correction voltage V_{φ} based on the detected time-variant amplitude \sqrt{I²+Q²} of the first equalized digital signal 56.

The second filter circuit 38 is configured to apply a second complex filter H_{ET}(s) to the digital signal 54 to generate a second equalized digital signal 58. The second envelope detector 40 is configured to detect the time-variant amplitude \sqrt{I²+Q²} of the second equalized digital signal 58. The amplitude correction LUT circuit 42 may include an isogain LUT (not shown) and is configured to generate the modulated amplitude correction voltage V_{AM} based on the detected time-variant amplitude \sqrt{I²+Q²} of the second equalized digital signal 58. The combiner 44 is configured to combine the modulated phase correction voltage V_{φ} and the modulated amplitude correction voltage V_{AM} to generate a modulated phase-amplitude correction voltage V_{φ-AM}.

The voltage LUT circuit 46 may include a voltage LUT (not shown) and is configured to generate a modulated target voltage V_{CC-TGT} based on the detected time-variant amplitude \sqrt{I²+Q²} of the second equalized digital signal 58. In one embodiment, the modulated target voltage V_{CC-TGT} can be an envelope tracking (ET) modulated target voltage for generating the modulated voltage V_{CC} as an ET modulated voltage. In another embodiment, the modulated target voltage V_{CC-TGT} can be an average power tracking (APT) modulated target voltage for generating the modulated voltage V_{CC} as an APT modulated voltage. The modulator circuit 48 is configured to generate a digital differential signal D_{DIFF} that includes the modulated phase-amplitude correction voltage V_{φ-AM} and the modulated target voltage V_{CC-TGT}. The DAC 50 is configured to convert the digital differential signal D_{DIFF} into the modulated differential signal S_{DIFF}.

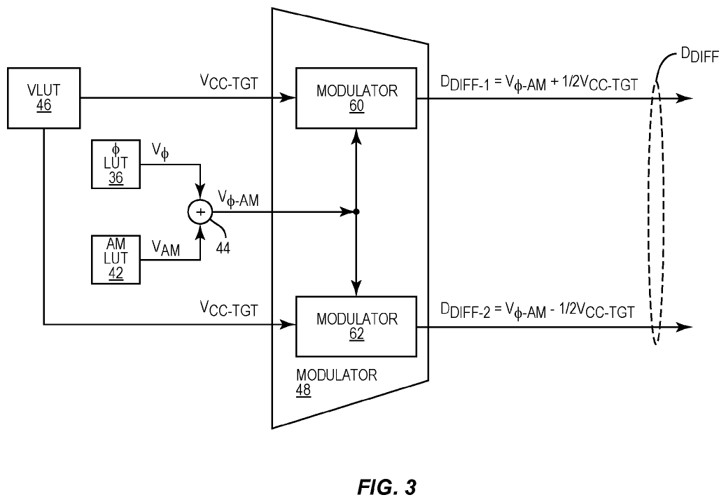

FIG. 3 is a schematic diagram providing an exemplary illustration of the digital differential signal DDIFF generated according to the embodiment of FIG. 2. Common elements between FIGS. 2 and 3 are shown therein with common element numbers and will not be re-described herein.

Herein, the modulator circuit 48 further includes a first modulator 60 and a second modulator 62. The first modulator 60 is configured to generate a first digital differential signal D_{DIFF-1} of the digital differential signal D_{DIFF} and the second modulator 62 is configured to generate a second digital differential signal D_{DIFF-2} of the digital differential signal D_{DIFF}. Specifically, the first modulator 60 generates the first digital differential signal D_{DIFF-1} by adding one-half (½) of the modulated target voltage V_{CC-TGT} to the modulated phase-amplitude correction voltage V_{φ-AM} (D_{DIFF-1}=V_{φ-AM}+½V_{CC-TGT}). The second modulator 62 generates the second digital differential signal D_{DIFF-2} by subtracting one-half (½) of the modulated target voltage Vcc-TGT from the modulated phase-amplitude correction voltage V_{φ-AM} (D_{DIFF-2}=V_{φ-AM}−½V_{CC-TGT}). In other words, the digital differential signal D_{DIFF} includes a common signal (a.k.a. the modulated phase-amplitude correction voltage V_{φ-AM}) and a differential signal (a.k.a. the modulated target voltage V_{CC-TGT}).

With reference back to FIG. 2, the PMIC 18A can include a voltage modulation circuit 64 and a splitter circuit 66. The voltage modulation circuit 64 is configured to extract the modulated target voltage V_{CC-TGT} from the modulated differential signal S_{DIFF} and generate the modulated voltage V_{CC} based on the modulated target voltage V_{CC-TGT}. The splitter circuit 66 is configured to extract the modulated phase-amplitude correction voltage V_{φ-AM} from the modulated differential signal S_{DIFF} and split the modulated phase-amplitude correction voltage V_{φ-AM} into the modulated phase correction voltage Vo and the modulated amplitude correction voltage V_{AM}.

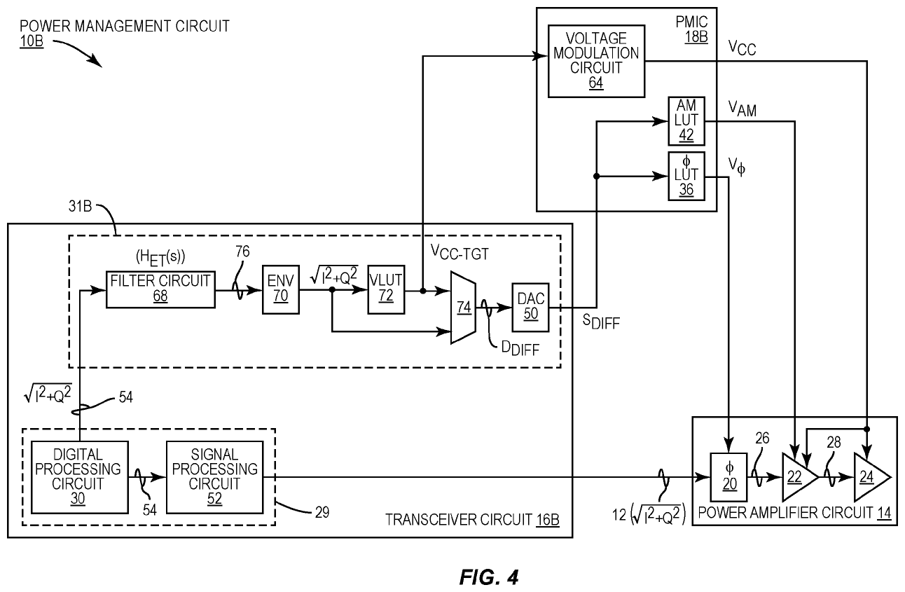

FIG. 4 is a schematic diagram providing an exemplary illustration of a power management circuit 10B configured according to another embodiment of the present disclosure. Common elements between FIGS. 1, 2, and 4 are shown therein with common element numbers and will not be re-described herein.

Herein, the power management circuit 10B includes a transceiver circuit 16B and a PMIC 18B that are functionally equivalent to the transceiver circuit 16 and the PMIC 18 in FIG. 1. According to an embodiment of the present disclosure, the transceiver circuit 16B includes a second signal processing circuit 31B, which includes a filter circuit 68, an envelope detector 70, a voltage LUT circuit 72, and a modulator circuit 74. The filter circuit 68 is configured to apply a complex filter H_{ET}(s) to the digital signal 54 to generate an equalized digital signal 76. The envelope detector 70 is configured to detect the time-variant amplitude \sqrt{I²+Q²} of the equalized digital signal 76. The voltage LUT circuit 72 may include a voltage LUT (not shown) and is configured to generate the modulated target voltage VCc-TGT based on the detected time-variant amplitude \sqrt{I²+Q²} of the equalized digital signal 76. The voltage LUT circuit 72 may be coupled to the voltage modulation circuit 64 via an RF frontend (RFFE) interface to thereby provide the modulated target voltage V_{CC-TGT} to the voltage modulation circuit 64. The modulator circuit 74 is configured to generate a digital differential signal D_{DIFF} that includes the time-variant amplitude \sqrt{I²+Q²} of the equalized digital signal 76 and the modulated target voltage Vcc-TGT.

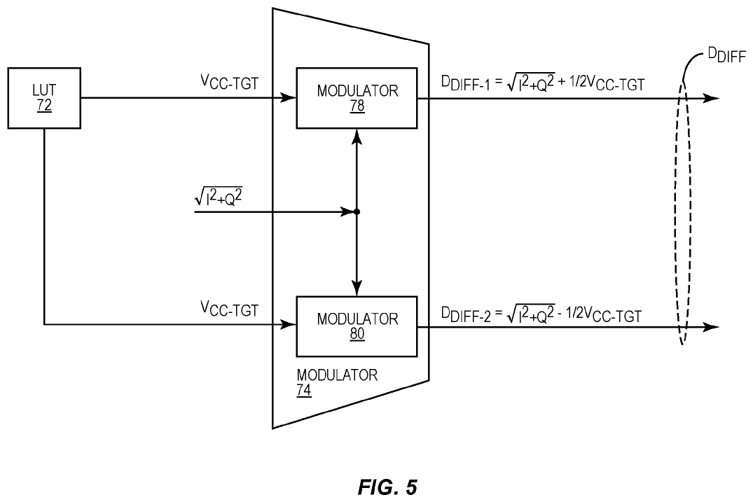

FIG. 5 is a schematic diagram providing an exemplary illustration of the digital differential signal DDIFF generated according to the embodiment of FIG. 4. Common elements between FIGS. 4 and 5 are shown therein with common element numbers and will not be re-described herein.

Herein, the modulator circuit 74 further includes a first modulator 78 and a second modulator 80. The first modulator 78 is configured to generate a first digital differential signal D_{DIFF-1} of the digital differential signal D_{DIFF} and the second modulator 80 is configured to generate a second digital differential signal D_{DIFF-2} of the digital differential signal D_{DIFF}. Specifically, the first modulator 78 generates the first digital differential signal D_{DIFF-1} by adding one-half (½) of the modulated target voltage V_{CC-TGT} to the time-variant amplitude \sqrt{I²+Q²} of the equalized digital signal 76 (D_{DIFF-1}=\sqrt{I²+Q²}+½V_{CC-TGT}). The second modulator 80 generates the second digital differential signal D_{DIFF-2} by subtracting one-half (½) of the modulated target voltage V_{CC-TGT} from the time-variant amplitude \sqrt{I²+Q²} of the equalized digital signal 76 (D_{DIFF-2}=\sqrt{I²+Q²} −1/2V_{CC-TGT}). In other words, the digital differential signal DDIFF includes a common signal (a.k.a. the time-variant amplitude \sqrt{I²+Q²} of the equalized digital signal 76) and a differential signal (a.k.a. the modulated target voltage V_{CC-TGT}).

With reference back to FIG. 4, the PMIC 18B can include the voltage modulation circuit 64, the phase correction LUT circuit 36, and the amplitude correction LUT circuit 42. The voltage modulation circuit 64 is configured to generate the modulated voltage V_{CC} based on the modulated target voltage V_{CC-TGT}. The phase correction LUT circuit 36 is configured to extract the time-variant amplitude \sqrt{I²+Q²} from the modulated differential signal S_{DIFF} and generate the modulated phase correction voltage V_{φ}. The amplitude correction LUT circuit 42 is configured to extract the time-variant amplitude \sqrt{I²+Q²} from the modulated differential signal S_{DIFF} and generate the modulated amplitude correction voltage V_{AM}.

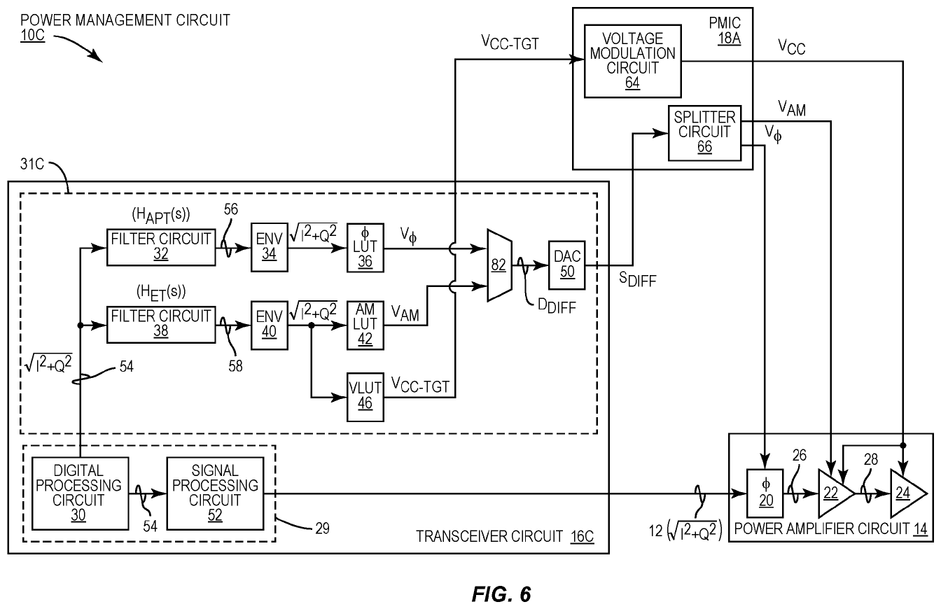

FIG. 6 is a schematic diagram providing an exemplary illustration of a power management circuit 10C configured according to one embodiment of the present disclosure. Common elements between FIGS. 1, 2, and 6 are shown therein with common element numbers and will not be re-described herein.

Herein, the power management circuit 10C includes a transceiver circuit 16C that is functionally equivalent to the transceiver circuit 16 in FIG. 1. In an embodiment, the transceiver circuit 16C includes a second signal processing circuit 31C. Herein, the phase correction LUT circuit 36 and the amplitude correction LUT circuit 42 are configured to provide the modulated phase correction voltage V_{φ} and the modulated amplitude correction voltage V_{AM} to a modulator 82 that generates the modulated differential signal S_{DIFF}. The voltage LUT circuit 46 is configured to provide the modulated target voltage V_{CC-TGT} to the voltage modulation circuit 64 for generating the modulated voltage V_{CC}.

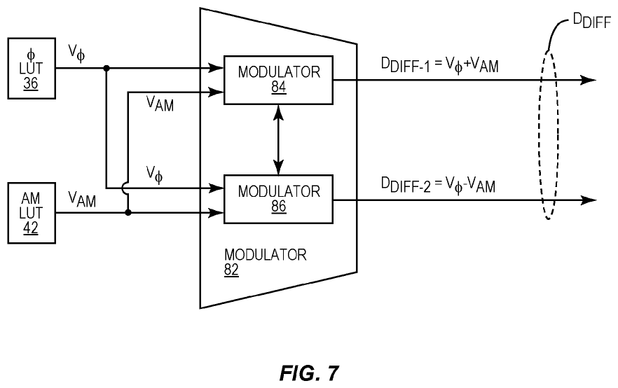

FIG. 7 is a schematic diagram providing an exemplary illustration of the digital differential signal DDIFF generated according to the embodiment of FIG. 6. Common elements between FIGS. 6 and 7 are shown therein with common element numbers and will not be re-described herein.

Herein, the modulator circuit 82 further includes a first modulator 84 and a second modulator 86. The first modulator 84 is configured to generate a first digital differential signal DDIFF-1 Of the digital differential signal DDIFF and the second modulator 86 is configured to generate a second digital differential signal D_{DIFF-2} of the digital differential signal D_{DIFF}. Specifically, the first modulator 84 generates the first digital differential signal D_{DIFF-1} by adding the modulated amplitude correction voltage V_{AM} to the modulated phase correction voltage V_{φ} and (D_{DIFF-1}=V_{φ}+V_{AM}). The second modulator 86 generates the second digital differential signal D_{DIFF-2} by subtracting the modulated amplitude correction voltage V_{AM} from the modulated amplitude correction voltage V_{AM} (D_{DIFF-2}=V_{φ}−V_{AM}). In other words, the digital differential signal D_{DIFF} includes a common signal (a.k.a. the modulated phase correction voltage V_{φ}) and a differential signal (a.k.a. the modulated amplitude correction voltage V_{AM}).

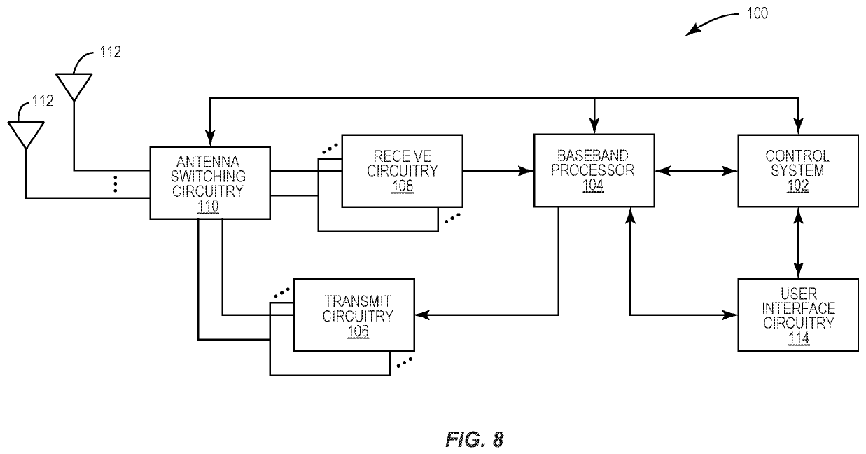

The power management circuit 10A of FIG. 2, the power management circuit 10B of FIG. 4, and the power management circuit 10C of FIG. 6 can be provided in a user element to enable bandwidth adaptation according to embodiments described above. In this regard, FIG. 8 is a schematic diagram of an exemplary user element 100 wherein the power management circuit 10A of FIG. 2, the power management circuit 10B of FIG. 4, and the power management circuit 10C of FIG. 6 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

1. A power management circuit comprising:
a transceiver circuit configured to:
generate a digital signal having a time-variant amplitude
and convert the digital signal into a radio frequency (RF) signal associated with the time-variant amplitude; and
generate a modulated differential signal based on the time-variant amplitude; and
a power management integrated circuit configured to generate a modulated voltage, a modulated amplitude correction voltage, and a modulated phase correction voltage based on the modulated differential signal.

2. The power management circuit of claim 1, further comprising a power amplifier circuit, the power amplifier circuit comprising:
a phase shifter circuit configured to perform a phase adjustment on the RF signal based on the modulated phase correction voltage to generate a phase-adjusted RF signal;
a driver stage amplifier coupled to the phase shifter circuit and configured to:
perform an amplitude adjustment on the phase-adjusted RF signal based on the modulated amplitude correction voltage to generate a phase-amplitude-adjusted RF signal ; and
amplify the phase-amplitude-adjusted RF signal based on the modulated voltage; and
an output stage amplifier coupled to the driver stage amplifier and configured to further amplify the amplified phase-amplitude-adjusted RF signal based on the modulated voltage.

3. The power management circuit of claim 1, wherein the transceiver circuit comprises:
a digital processing circuit configured to generate the digital signal associated with the time-variant amplitude;
a first filter circuit configured to apply a first complex filter to the digital signal to generate a first equalized digital signal;
a first envelope detector configured to detect the time-variant amplitude of the first equalized digital signal;
a phase correction lookup table (LUT) circuit configured to generate the modulated phase correction voltage based on the detected time-variant amplitude of the first equalized digital signal;
a second filter circuit configured to apply a second complex filter to the digital signal to generate a second equalized digital signal;
a second envelope detector configured to detect the time-variant amplitude of the second equalized digital signal;
an amplitude correction LUT circuit configured to generate the modulated amplitude correction voltage based on the detected time-variant amplitude of the second equalized digital signal;
a combiner configured to combine the modulated phase correction voltage and the modulated amplitude correction voltage to generate a modulated phase-amplitude correction voltage;
a voltage LUT circuit configured to generate a modulated target voltage based on the detected time-variant amplitude of the second equalized digital signal;
a modulator circuit configured to generate a digital differential signal comprising the modulated phase-amplitude correction voltage and the modulated target voltage; and
a digital to analog converter, DAC, configured to convert the digital differential signal into the modulated differential signal.

4. The power management circuit of claim 3, wherein the modulated differential signal comprises:
a common component comprising the modulated phase-amplitude correction voltage; and
a differential component comprising a positive one-half (½) of the modulated target voltage and a negative one-half (½) of the modulated target voltage.

5. The power management circuit of claim 4, wherein the modulator circuit comprises:
a first modulator configured to add one-half (½) of the modulated target voltage to the modulated phase-amplitude correction voltage to thereby generate a first digital differential signal comprising the common component and the positive one-half (½) of the modulated target voltage; and
a second modulator configured to subtract one-half (½) of the modulated target voltage from the modulated phase-amplitude correction voltage to thereby generate a second digital differential signal comprising the common component and the negative one-half (½) of the modulated target voltage.

6. The power management circuit of claim 4, wherein the PMIC comprises:
a voltage modulation circuit configured to:
extract the modulated target voltage from the modulated differential signal ; and
generate the modulated voltage based on the modulated target voltage; and
a splitter circuit configured to:
extract the modulated phase-amplitude correction voltage from the modulated differential signal; and
split the modulated phase-amplitude correction voltage into the modulated phase correction voltage and the modulated amplitude correction voltage.

7. The power management circuit of claim 1, wherein the transceiver circuit comprises:
a digital processing circuit configured to generate the digital signal associated with the time-variant amplitude;
a filter circuit configured to apply a complex filter to the digital signal to generate an equalized digital signal;
an envelope detector configured to detect the time-variant amplitude of the equalized digital signal;
a voltage lookup table (LUT) circuit configured to generate a modulated target voltage based on the detected time-variant amplitude of the equalized digital signal
a modulator circuit configured to generate a digital differential signal comprising the time-variant amplitude of the equalized digital signal and the modulated target voltage ; and
a digital to analog converter (DAC) configured to convert the digital differential signal into the modulated differential signal.

8. The power management circuit of claim 7, wherein the modulated differential signal comprises:
a common component comprising the time-variant amplitude of the equalized digital signal; and
a differential component comprising a positive one-half (½) of the modulated target voltage and a negative one-half (½) of the modulated target voltage.

9. The power management circuit of claim 8, wherein the modulator circuit comprises:
a first modulator configured to add one-half (½) of the modulated target voltage to the time-variant amplitude of the equalized digital signal to thereby generate a first digital differential signal comprising the common component and the positive one-half (½) of the modulated target voltage; and
a second modulator configured to subtract one-half (½) of the modulated target voltage from the time-variant amplitude of the equalized digital signal to thereby generate a second digital differential signal comprising the common component and the negative one-half (½) of the modulated target voltage.

10. The power management circuit of claim 8, wherein the PMIC comprises:
a voltage modulation circuit configured to:
receive the modulated target voltage from the voltage LUT circuit; and
generate the modulated voltage based on the modulated target voltage;
a phase correction LUT circuit configured to generate the modulated phase correction voltage based on the common component of the modulated differential signal; and
an amplitude correction LUT circuit configured to generate the modulated amplitude correction voltage based on the common component of the modulated differential signal.

11. The power management circuit of claim 1, wherein the transceiver circuit comprises:
a digital processing circuit configured to generate the digital signal associated with the time-variant amplitude;
a first filter circuit configured to apply a first complex filter to the digital signal to generate a first equalized digital signal;
a first envelope detector configured to detect the time-variant amplitude of the first equalized digital signal;
a phase correction lookup table (LUT) circuit configured to generate the modulated phase correction voltage based on the detected time-variant amplitude of the first equalized digital signal;
a second filter circuit configured to apply a second complex filter to the digital signal to generate a second equalized digital signal;
a second envelope detector configured to detect the time-variant amplitude of the second equalized digital signal;
an amplitude correction LUT circuit configured to generate the modulated amplitude correction voltage based on the detected time-variant amplitude of the second equalized digital signal;
a voltage LUT circuit configured to generate a modulated target voltage based on the detected time-variant amplitude of the second equalized digital signal;
a modulator circuit configured to generate a digital differential signal comprising the modulated phase correction voltage and the modulated amplitude correction voltage; and
a digital to analog converter (DAC) configured to convert the digital differential signal into the modulated differential signal.

12. The power management circuit of claim 11, wherein the modulated differential signal comprises:
a common component comprising the modulated amplitude correction voltage; and
a differential component comprising a positive modulated amplitude correction voltage and a negative modulated amplitude correction voltage.

13. The power management circuit of claim 12, wherein the modulator circuit comprises:
a first modulator configured to add the modulated amplitude correction voltage to the modulated phase correction voltage to thereby generate a first digital differential signal comprising the common component and the positive modulated amplitude correction voltage; and
a second modulator configured to subtract the modulated amplitude correction voltage from the modulated phase correction voltage to thereby generate a second digital differential signal comprising the common component and the negative modulated amplitude correction voltage.

14. A transceiver circuit comprising:
a first signal processing circuit configured to generate a digital signal having a time-variant amplitude and convert the digital signal into a radio frequency (RF) signal associated with the time-variant amplitude; and
a second signal processing circuit configured to generate a modulated differential signal based on the time-variant amplitude.

15. The transceiver circuit of claim 14, wherein the first signal processing circuit comprises:
a digital processing circuit configured to generate the digital signal associated with the time-variant amplitude; and
a signal processing circuit configured to convert the digital signal into the RF signal associated with the time-variant amplitude.

16. The transceiver circuit of claim 15, wherein the second signal processing circuit comprises:
a first filter circuit configured to apply a first complex filter to the digital signal to generate a first equalized digital signal ;
a first envelope detector configured to detect the time-variant amplitude of the first equalized digital signal;
a phase correction lookup table (LUT) circuit configured to generate a modulated phase correction voltage based on the detected time-variant amplitude of the first equalized digital signal;
a second filter circuit configured to apply a second complex filter to the digital signal to generate a second equalized digital signal;
a second envelope detector configured to detect the time-variant amplitude of the second equalized digital signal;
an amplitude correction LUT circuit configured to generate a modulated amplitude correction voltage based on the detected time-variant amplitude of the second equalized digital signal;
a combiner configured to combine the modulated phase correction voltage and the modulated amplitude correction voltage to generate a modulated phase-amplitude correction voltage ;
a voltage LUT circuit configured to generate a modulated target voltage based on the detected time-variant amplitude of the second equalized digital signal;
a modulator circuit configured to generate a digital differential signal comprising the modulated phase-amplitude correction voltage and the modulated target voltage; and
a digital to analog converter, DAC, configured to convert the digital differential signal into the modulated differential signal.

17. The transceiver circuit of claim 16, wherein the modulated differential signal comprises:
a common component comprising the modulated phase-amplitude correction voltage; and
a differential component comprising a positive one-half (½) of the modulated target voltage and a negative one-half (½) of the modulated target voltage.

18. The transceiver circuit of claim 17, wherein the modulator circuit comprises:
a first modulator configured to add one-half (½) of the modulated target voltage to the modulated phase-amplitude correction voltage to thereby generate a first digital differential signal comprising the common component and the positive one-half (½) of the modulated target voltage; and
a second modulator configured to subtract one-half (½) of the modulated target voltage from the modulated phase-amplitude correction voltage to thereby generate a second digital differential signal comprising the common component and the negative one-half (½) of the modulated target voltage.

19. The transceiver circuit of claim 15, wherein the second signal processing circuit comprises:
a filter circuit configured to apply a complex filter to the digital signal to generate an equalized digital signal;
an envelope detector configured to detect the time-variant amplitude of the equalized digital signl;
a voltage lookup table (LUT) circuit configured to generate a modulated target voltage based on the detected time-variant amplitude of the equalized digital signal;
a modulator circuit configured to generate a digital differential signal comprising the time-variant amplitude of the equalized digital signal and the modulated target voltage ; and
a digital to analog converter (DAC) configured to convert the digital differential signal into the modulated differential signal.

20. The transceiver circuit of claim 19, wherein the modulated differential signal comprises:
a common component comprising the time-variant amplitude of the equalized digital signal; and
a differential component comprising a positive one-half (½) of the modulated target voltage and a negative one-half (½) of the modulated target voltage.

21. The transceiver circuit of claim 20, wherein the modulator circuit comprises:
a first modulator configured to add one-half (½) of the modulated target voltage to the time-variant amplitude of the equalized digital signal to thereby generate a first digital differential signal comprising the common component and the positive one-half (½) of the modulated target voltage; and
a second modulator configured to subtract one-half (½) of the modulated target voltage from the time-variant amplitude of the equalized digital signal to thereby generate a second digital differential signal comprising the common component and the negative one-half (½) of the modulated target voltage.

22. The transceiver circuit of claim 15, wherein the second signal processing circuit comprises:
a first filter circuit configured to apply a first complex filter to the digital signal to generate a first equalized digital signal;
a first envelope detector configured to detect the time-variant amplitude of the first equalized digital signal;
a phase correction lookup table (LUT) circuit configured to generate the modulated phase correction voltage based on the detected time-variant amplitude of the first equalized digital signal;
a second filter circuit configured to apply a second complex filter to the digital signal to generate a second equalized digital signal;
a second envelope detector configured to detect the time-variant amplitude of the second equalized digital signal;
an amplitude correction LUT circuit configured to generate the modulated amplitude correction voltage based on the detected time-variant amplitude of the second equalized digital signal;
a voltage LUT circuit configured to generate a modulated target voltage based on the detected time-variant amplitude of the second equalized digital signal;
a modulator circuit configured to generate a digital differential signal comprising the modulated phase correction voltage and the modulated amplitude correction voltage; and
a digital to analog converter (DAC), configured to convert the digital differential signal into the modulated differential signal.

23. The transceiver circuit of claim 22, wherein the modulated differential signal comprises:
a common component comprising the modulated amplitude correction voltage; and
a differential component comprising a positive modulated amplitude correction voltage and a negative modulated amplitude correction voltage.

24. The transceiver circuit of claim 23, wherein the modulator circuit comprises:
a first modulator configured to add the modulated amplitude correction voltage to the modulated phase correction voltage to thereby generate a first digital differential signal comprising the common component and the positive modulated amplitude correction voltage; and
a second modulator configured to subtract the modulated amplitude correction voltage from the modulated phase correction voltage to thereby generate a second digital differential signal comprising the common component and the negative modulated amplitude correction voltage.
